(19) United States
(12) Patent Application Publication
(10) Pub. No.: US 2026/0314440 A1
(43) Pub. Date: Oct. 8, 2026

(54) HIGH-DENSITY INTERCONNECT REGION WITH MIXED BUMP WIDTHS

(71) Applicant: Intel Corporation, Santa Clara, CA (US)

(72) Inventors: Andrew Paul Collins, Chandler, AZ (US); Sujit Sharan, Chandler, AZ (US); Jianyong Xie, Chandler, AZ (US); Debendra Mallik, Chandler, AZ (US)

(73) Assignee: Intel Corporation, Santa Clara, CA (US)

(21) Appl. No.: 19/170,218

(22) Filed: Apr. 4, 2025

(51) Int. Cl. H01L 23/00; H01L 23/538; H01L 25/07

(52) U.S. Cl. CPC H10W 70/611; H10W 70/614; H10W 70/65; H10W 90/00; H10W 72/227; H10W 72/248; H10W 90/722

(57) ABSTRACT

Microelectronic components and assemblies that have a high-density interconnect region with mixed bump widths may enable wafer sort-on-solder techniques with lower die area requirements and with improved power delivery to a high-density interconnect region. In one example, a microelectronic assembly includes two dies stacked over and coupled with one another and a plurality of conductive interconnects including a solder material (e.g., solder bumps/joints) between and coupled with the dies, where the plurality of conductive interconnects include first conductive interconnects with a first width and second conductive interconnects with a second with that is greater than the first width, and where the second conductive interconnects are coplanar and interleaved with the first conductive interconnects.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes. Some components in a package or assembly may be coupled with one another using solder.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a cross-sectional side view of a microelectronic assembly with a high-density interconnect region with mixed bump widths, according to some embodiments of the present disclosure.

FIG. 1B is a block diagram of an example of a die that may be included in an assembly with a high-density interconnect region with mixed bump widths, according to some embodiments of the present disclosure.

FIG. 2 illustrates a cross-sectional side view of an example of a microelectronic assembly having a high-density interconnect region with mixed bump widths, according to some embodiments of the present disclosure.

FIGS. 3A-3B illustrate cross-sectional side views of examples of microelectronic assemblies having a high-density interconnect region with mixed bump widths, according to some embodiments of the present disclosure.

FIG. 4 is a cross-sectional side view of another example of a microelectronic assembly having a high-density interconnect region with mixed bump widths, according to some embodiments of the present disclosure.

FIGS. 5A-5E illustrate examples of interconnect patterns in which smaller-width interconnects and larger-width interconnects are interleaved, according to some embodiments of the present disclosure.

FIG. 6 is a flow diagram of a method of making a microelectronic assembly with a high-density interconnect including mixed bump widths, in accordance with any example described herein.

FIG. 7 illustrates cross-sectional side views of an example assembly at different stages of making a microelectronic assembly in accordance with the method of FIG. 6, according to some embodiments of the present disclosure.

FIG. 8 is a flow diagram of a method of performing sort testing on solder bumps of a wafer that includes a high-density interconnect including mixed bump widths, according to some embodiments of the present disclosure.

FIG. 9 is a cross-sectional view of the method of FIG. 8, according to some embodiments of the present disclosure.

FIG. 10 is a top view of a wafer and dies that may include any of the IC structures disclosed herein, in accordance with any of the embodiments disclosed herein.

FIG. 11 is a side, cross-sectional view of an IC package that may include an assembly or any of the IC structures disclosed herein, in accordance with various embodiments.

FIG. 12 is a side, cross-sectional view of an IC device assembly that may include an assembly or any of the IC structures disclosed herein, in accordance with any of the embodiments disclosed herein.

FIG. 13 is a block diagram of an example electrical device that may include an assembly or any of the IC structures disclosed herein, in accordance with any of the embodiments disclosed herein.

### DETAILED DESCRIPTION

Disclosed herein are microelectronic components and assemblies that have a high-density interconnect region with mixed bump widths. The systems, methods, and devices of this disclosure each have several innovative aspects, no single one of which is solely responsible for all desirable attributes disclosed herein. Details of one or more implementations of the subject matter described in this specification are set forth in the description below and the accompanying drawings.

Wafer sort refers to a stage in semiconductor manufacturing where integrated circuits on a wafer are electrically tested before being singulated into individual dies. During this process, sort probes make contact with conductive elements on the wafer to provide power to the circuits and perform testing (e.g., loop-back testing or other types of testing) to identify functional and non-functional chips, and to enable binning chips according to their performance characteristics. One technique for performing wafer sort involves using dedicated probe pads, where the sort probes make contact directly with the probe pads. Wafer sort techniques that probe on dedicated probe pads are carried out prior to providing solder bumps on the wafer. Another technique involves probing on solder bumps (referred to as “sort probing on solder” or “sort on solder”) after providing solder bumps on the wafer. Sort-probing-on-solder techniques conventionally utilize solder bumps having a larger width that are located in a dedicated bump area that is outside of and separate from fine-pitch interconnects such as I/O interconnects. A benefit of the probe-on-solder approach versus an approach that uses dedicated probe pads is that such large-pitch solder bumps can be both utilized during the sort-testing phase as well as during device operation after the die is attached to a substrate. Sorting on solder bumps after die solder bumping and wafer singulation may enable any additional yield loss due to those processes to be captured. As the area of fine-pitch I/O solder bumps increases to accommodate higher bandwidth demands (e.g., the bandwidth increase in HBM4 (High Bandwidth Memory version 4, currently in discussion by JEDEC) compared to HBM 3 (HBM version 3, JESD 238A originally published in January 2023)), sort probing on the larger solder bumps becomes more challenging, e.g., due to the increased distance between the probe locations and fine-pitch I/O solder bumps. Additionally, sort probing on solder techniques may experience an area penalty due to the inclusion of a separate dedicated area of larger-width solder bumps.

According to examples described herein, a combination of large-width and small-width conductive bumps (mixed-width bumps) within a high-density interconnect region may enable sort-on-solder probing without the need for a dedicated larger solder bump area. Additionally, a high-density interconnect region with mixed bump widths as described herein may enable a lower-resistance vertical power delivery path for more current delivery per unit of chip area without increasing the depth of the I/O bumps and channel length. In one example, a microelectronic assembly includes two dies stacked over and coupled with one another and a plurality of conductive interconnects including a solder material (e.g., solder bumps/joints) between and coupled with the dies. In one such example, the plurality of conductive interconnects include first conductive interconnects with a first width and second conductive interconnects with a second with that is greater than the first width, where the second conductive interconnects are coplanar and interleaved with the first conductive interconnects.

IC structures, microelectronic components and microelectronic assemblies that have a high-density interconnect region with mixed bump widths as described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of microelectronic components and assemblies that have a high-density interconnect region with mixed bump widths as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

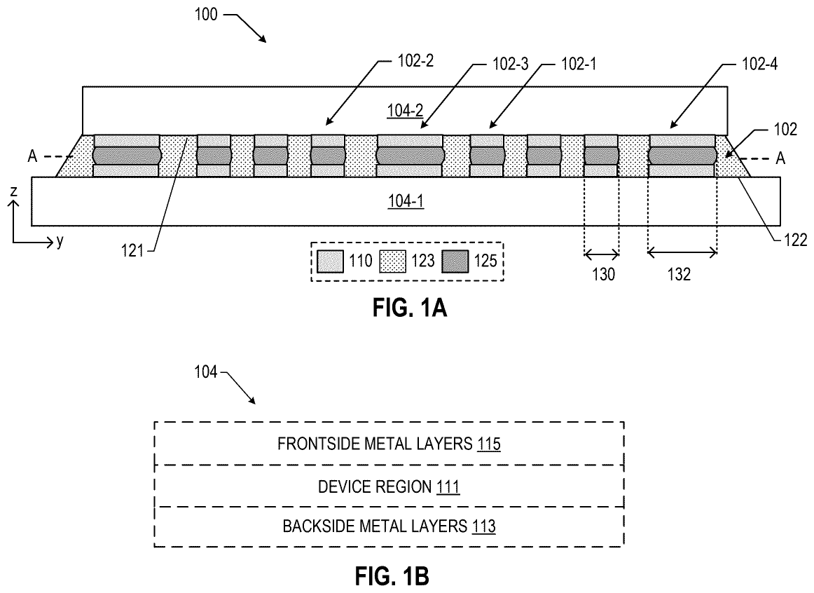

FIG. 1A is a cross-sectional side view of a microelectronic assembly 100 with a high-density interconnect region with mixed bump widths. A number of elements referred to in the description of FIG. 1A (and subsequent figures) with reference numerals are illustrated in these drawings with different patterns, with a legend showing the correspondence between the reference numerals and patterns being provided at the bottom of each drawing page containing such figures. For example, the legend illustrates that FIG. 1A uses different patterns to show conductive pads 110 and a solder material 125.

The microelectronic assembly 100 if FIG. 1A includes a first die 104-1 and a second die 104-2 over and bonded with the first die 104-1. The dies 104-1 and 104-2 may be, for example, discrete IC structures, which may also be referred to as IC dies, chips, chiplets, or microelectronic components. IC dies in an assembly or system may include logic to provide a particular functionalities in the IC device or system. For example, an assembly may include one or more compute dies, memory dies, cache dies, accelerator dies, etc. In one example, a compute die may be or include one or more of a central processor unit (CPU), graphics processor unit (GPU), application-specific integrated circuits (ASICs), field programmable gate array (FPGA), data processing unit (DPU), vision processor unit (VPU), and/or other compute logic. A memory die may include one or more memory arrays (e.g., dynamic random access memory (DRAM) and/or static random access memory (SRAM) arrays). A cache die may include one or more memory arrays (e.g., an SRAM array or other low latency memory). Dies may have more than one type of device, for example, a compute die may also include one or more memory arrays, and a memory die may include compute logic. In some examples, the dies 104-1 and 104-2 may represent a stack of dies. For example, the die 104-2 may include a stack of memory dies implemented in accordance with a stacked memory architecture and/or standard. In some examples, the die 104-1 may represent a substrate, bridge die, or a substrate with an embedded bridge die, and the die 104-2 may represent IC die with devices.

The dies 104-1 and 104-2 may include a device region and one or more interconnect layers, such as shown in FIG. 1B. FIG. 1B shows a diagram of a die 104 with a device region 111, frontside metal layers 115 over the device region, and backside metal layers 113. The device region includes devices formed over a substrate, and may include or be referred to as a front end of line (FEOL) layer. The device region 111 may include frontend devices (e.g., frontend transistors such as FinFETs, nanowire/nanoribbon transistors, planar transistors, frontend memory cells, or other frontend devices). The frontside metal layers 115 are over a front side of the device region, and the backside metal layers 113 are over a back side of the device region. The metal layers 115, 113 may also be referred to as back end of line (BEOL) layers. Various metal layers 115, 113 may be used to interconnect the various inputs and outputs of the devices (e.g., logic devices or memory devices) in the device regions 111. In one example, each of the metal layers may include vias and lines/trenches, as discussed in further detail below. The metal layers 115 and 113 may also include devices (e.g., backend devices). Some dies may include more, fewer, and or different layers/regions than shown in FIG. 1B, and the device region 111, frontside metal layers 115, and backside metal layers 113 are shown with dashed lines to indicate that different types of dies may not include one or more of these layers. For example, some dies may have only a device region and frontside metal layers 115, but lack backside metal layers. Other dies may lack a device region (e.g., in the case of a passive interconnect die) and include only interconnect layers.

Referring again to FIG. 1A, the microelectronic assembly 100 includes a plurality of coplanar conductive interconnects 102 between and coupled with the first die 104-1 and the second die 104-2. The conductive interconnects 102 may include a solder material 125 (e.g., may include or be a solder bumps/solder balls or solder joints) between conductive elements, such as the conductive pads 110 depicted in FIG. 1A. In the example illustrated in FIG. 1A, conductive pads 110 are on a side or face 122 of the die 104-1 and a side or face 121 of the die 104-2. The conductive pads 110 (which may also be referred to as conductive contacts) include a conductive material, such as copper or any other suitable conductive material. The pads 110 may have a variety of shapes, e.g., rectangular, square, hexagonal, octagonal, round, or other shapes in a cross-section along the x-y plane as shown in FIG. 1A, where the x-axis goes into and comes out of the page. In some examples, conductive bumps may be arranged in an array, such as in ball grid array (BGA) assemblies. Conductive bumps may be formed to have various shapes (e.g., spherical/round, cylindrical, etc.), which may be deformed after bonding.

The conductive interconnects 102 include a conductive material (e.g., one or more metals), such as solder, copper, gold, or other suitable conductive material. Conductive interconnects 102 that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, conductive interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

In some examples, the conductive interconnects 102 are surrounded by an insulator material 123 (sometimes referred to as a filler or underfill material) in a plane with the conductive interconnects 102. The insulator material 123 may be provided according to any suitable method (e.g., deposited before or after formation of solder bumps), and may provide mechanical support to an interface layer with conductive interconnects 102. The insulator material 123 may be any suitable insulator material, such as silicon oxide, silicon carbide, silicon oxynitride, carbon-doped silicon oxide, spin-on-glass, boron-doped silicon oxide, an organic polymer, carbon, a carbon polymer, or any other suitable insulator material.

As can be seen in FIG. 1A, the conductive interconnects 102 include both smaller-width and larger-width interconnects interleaved with one another. Larger-width interconnects are interleaved with smaller-width interconnects if at least one larger-width interconnect is between two or more smaller-width interconnects. For example, the assembly 100 includes conductive interconnects 102-1 and 102-2 with a first width 130 and conductive interconnects 102-3 and 102-4 with a second width 132, where the width 132 is greater than the width 130, and where the width of an interconnect is a dimension of the interconnect in a plane substantially parallel with the dies 104-1, 104-2 or a substrate over which the dies are disposed. Note that not all conductive interconnects 102 are labeled in order to not clutter the drawing. The width of an interconnect 102 (e.g., the width 130 or the width 132) may be the width of a conductive pad 110 of the interconnect 102. For example, the interconnect 102-1 includes a portion including solder (e.g., a solder portion) between two pads 110, where the width 130 of the interconnect 102-1 may be defined as the width of one of the two pads (e.g., where the width is a dimension of a pad 110 along the y-axis as shown in FIG. 1A).

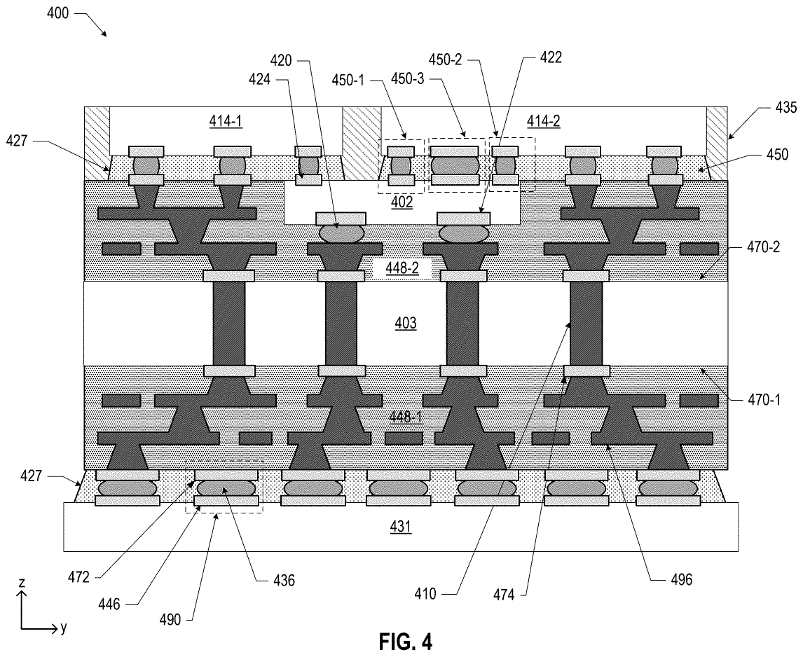

In some examples, the width 132 may be about 1.5 to 8 times the width 130, about 1.5 to 2.5 times the width 130, or about 1.7 to 2.3 times the width 130. In some examples, the width 132 is about 2 times the width 130. In some examples, the width 130 may be in a range of about 15 to 55 micron, about 35 to 55 micron, or about 25 to 35 micron. The width 132 may be in a range of about 30 to 130 micron or about 70 to 110 micron. In other examples, the widths 130 and 132 may be smaller than or greater than the above-mentioned ranges. In some examples, the interconnects 102-1 and 102-2 with a smaller width may represent input/output (I/O) interconnects for transmitting data signals (e.g., the interconnects 102-1 and 102-2 may be configured to be coupled with a signal line, such as a data signal line). In some examples, the interconnects 102-3, 102-4 with a larger width 132 may represent interconnects that are configured to be coupled with a voltage source or ground. In some examples, the interconnects 102-3, 102-4 with the larger width 132 may be formed at least in part from solder bumps that enable sort testing prior to assembly. The smaller-width and larger-width interconnects may be interleaved in a variety of patterns. For example, FIGS. 5A-5E, discussed below, illustrate views along the plane AA shown in FIG. 1A of examples of interconnect interleaving patterns.

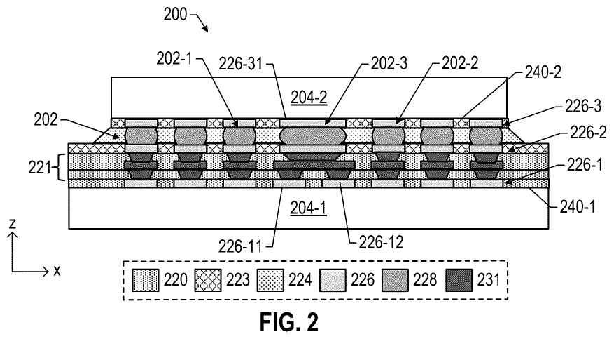

FIG. 2 illustrates a cross-sectional side view of an example of a microelectronic assembly 200 having a high-density interconnect region with mixed bump widths. The microelectronic assembly 200 includes two dies 204-1, 204-2 stacked over one another and bonded together with conductive interconnects 202 between conductive pads 226. The dies 204-1, 204-2 may be examples of the dies 104-1, 104-2 discussed above. The microelectronic assembly 200 includes conductive pads 226-1 on a face 240-1 of the die 204-1, and conductive pads 226-3 on a face 240-2 of the die 204-2. In the example illustrated in FIG. 2, the microelectronic assembly 200 includes redistribution layers (RDLs) 221 between the die 204-1 and the die 204-2. RDLs are interconnect layers over or on an integrated circuit structure, such as a die. In some examples RDLs may enable flexibility signal routing and pad interconnections (e.g., routing between conductive pads 226-1 and conductive pads 226-2). For example, the RDLs 221 include a conductive interconnects 231, which may include conductive lines and conductive vias (which may be referred to as pillars), with a dielectric material 220 between conductive interconnects. The dielectric material 220 may include silicon (e.g., in the case of a silicon-based interposer), include an organic dielectric material (e.g., in the case of an organic interposer), or both a dielectric material that includes silicon and an organic dielectric. Examples of silicon-based dielectric materials that may be included in one or more layers of the interposer 102 include silicon and one or more of oxygen and nitrogen (e.g., silicon oxide, silicon nitride, or silicon oxynitride). Examples of organic dielectric materials that may be included in one or more layers of the interposer 102 include a fire retardant grade 4 material (FR-4), bismaleimide triazine (BT) resin, polyimide materials, glass reinforced epoxy matrix materials, organic dielectrics with inorganic fillers (e.g., mold materials) or low-k and ultra low-k dielectric (e.g., carbon-doped dielectrics, fluorine-doped dielectrics, porous dielectrics, and organic polymeric dielectrics). The RDLs 221 may be formed using various thin film and/or printed circuit board (PCB) deposition processes, including sputtering and plating, electroless seed layer application, electroplating, printing, and/or other deposition processes. In some examples, the RDLs 221 may be formed on a panel carrier by laminating or spinning on a dielectric material, and creating conductive vias and lines by laser drilling and plating. The conductive interconnects 231 in the RDLs 221 may include any suitable conductive material, including one or more of: copper, aluminum, gold, silver, tungsten, and/or another conductive material.

The microelectronic assembly 200 includes conductive pads 226-2 on the RDLs 221, which may be surrounded by a solder mask material 223. Conductive interconnects 202 including a solder material 228 are between and coupled with the conductive pads 226-2 and 226-3, and may be surrounded by an insulator material 224. The insulator material 224 may be an example of the insulator material 123 of FIG. 1A. As can be seen in FIG. 2, the dies 204-1 and 204-2 are coupled with the conductive interconnects 202 having mixed widths. For example, the conductive interconnect 202-3, which is between the conductive interconnect 202-1 and the conductive interconnect 202-2, has a larger width than the conductive interconnects 202-1, 202-2.

In the example illustrated in FIG. 2, two smaller pads on the die 204-1 are coupled with one larger pad and the larger interconnect. Specifically, the interconnect 202-3 is coupled with two conductive pads 226-11, 226-12 at/on the face 240-1 of the die 204-1 and one conductive pad 226-31 at/on the face 240-2 of the die 204-2, where the one conductive pad 226-31 has a greater width than each of the conductive pads 226-11 and 226-12. In some examples, having a consistent contact pitch on the die 204-1 may have benefits, e.g., such as structural stability, which may be advantageous for some dies (e.g., bridge dies or other dies having a relatively small thickness). In other examples, the conductive pads 226-1 may include both smaller and larger pads (like the conductive pads 226-2). Note that although FIG. 2 illustrates two dies 204-1 and 204-2 bonded with one another, other examples may include more than two dies (e.g., more than one die may be coplanar with, stacked over, and bonded with the die 204-1, or one or more additional dies may be stacked over and bonded with the die 204-2). Additionally, although a certain number and arrangement of RDLs 221, conductive interconnects 231, and conductive interconnects 202 are shown in FIG. 2, other examples may include a different number or arrangement of such elements.

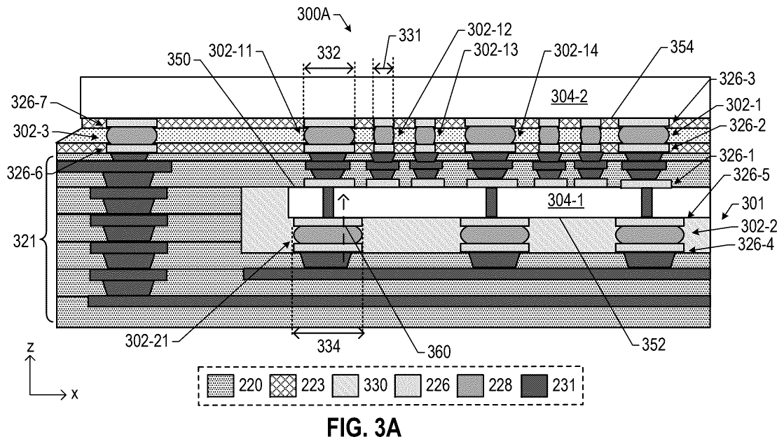

FIG. 3A illustrates a cross-sectional side view of another example of a microelectronic assembly 300A that has a high-density interconnect region with mixed bump widths. The microelectronic assembly 300A of FIG. 3A includes a substrate 301 with an embedded bridge die 304-1 (e.g., an embedded multi-die interconnect bridge (EMIB)), and high-density interconnects 302-1 with mixed bump widths between the embedded bride die 304-1 and another die 304-2. The substrate 301 includes a plurality of interconnect layers 321, which include conductive interconnects 231 (e.g., lines and vias) surrounded by a dielectric material 220. In some examples, the interconnect layers 321 may be an example of the RDLs 221 discussed above. In some examples, the bridge die 304-1 may include appropriate circuitry on/in a semiconductor substrate to connect at silicon-interconnect speeds with a small footprint. In some embodiments, a bridge die 304-1 may include active components, such as transistors and diodes in addition to bridge/interconnect circuitry including metallization traces, vias and passive components for enabling electrical coupling between two ICs; in other examples, a bridge die 304-1 may include bridge circuitry including metallization traces, vias and passive components for enabling electrical coupling between the die 304-2 and another die, and may not include active components.

In the example illustrated in FIG. 3A, conductive contacts 326-1 (e.g., pads) are on and coupled with a side or face 350 of the bridge die 304-1 that is facing the die 304-2 (e.g., a top face or top side). The microelectronic assembly 300A includes one or more interconnect layers 321 over the bridge die 304-1. Conductive contacts 326-2 are on and coupled with one of the interconnect layers 321 over the bridge die 304-1 (e.g., over a top interconnect layer 321). The interconnects 231 of the one or more interconnect layers 321 that are over the bridge die 304-1 are between and coupled with the conductive contacts 326-1 and the conductive contacts 326-2. Corresponding conductive contacts 326-3 (e.g., corresponding to the contacts 326-2) are on a side or face 354 of the die 304-2, where the face 354 of the die 304-2 is facing the face 350 of the bridge die 304-1 (e.g., the conductive contacts 326-3 are on a bottom face or substrate-facing side of the die 304-2). A solder material 228 of the conductive interconnects 302-1 is between and coupled with the conductive contacts 326-2 and the conductive contacts 326-3. As can be seen in FIG. 3A, the conductive interconnects 302-1 includes interconnects of different widths. For example, the microelectronic assembly 300A includes wider conductive interconnects (e.g., the conductive interconnects 302-11 and 302-14 with the width 332) interleaved with narrower width (e.g., fine pitch) interconnects between the bridge die 304-1 and the die 304-2 (e.g., the interconnects 302-12 and 302-13 with the width 331). In some examples, the interconnects with the width 331 may include I/O interconnects, and the interconnects with the width 332 may include interconnects for power and/or testing.

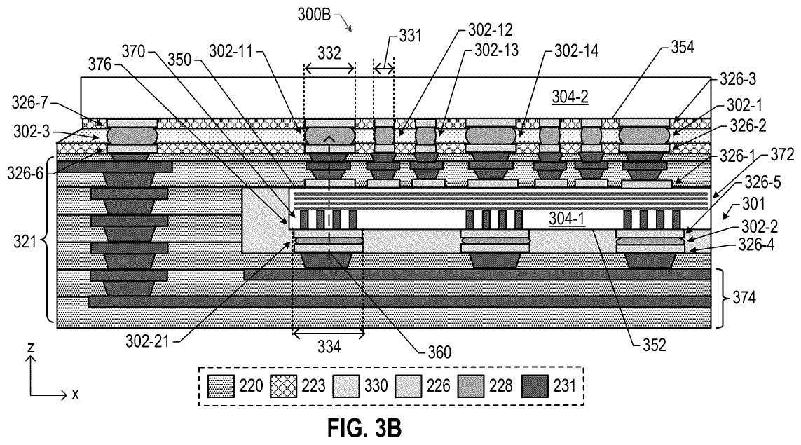

Thus, the bridge die 304-1 in FIG. 3A is conductively/electrically coupled with the die 304-2 via conductive contacts 326-1, metal lines and vias of one or more interconnect layers 321 disposed over the bridge die 304-1, conductive contacts 326-2, the solder material 228 of the conductive interconnects 302-1, and the conductive contacts 326-3. Although only a portion of the assembly 300A is shown in FIG. 3A, which shows a single die 304-2 over and bonded with the embedded bridge die 304-1, an assembly typically includes multiple dies (e.g., multiple dies like the die 304-2) coupled with a bridge die, such as depicted in FIG. 4, discussed below.

Referring again to FIG. 3A, the die 304-2 has a footprint that extends beyond the footprint of the die 304-1, so that a portion of the die 304-2 is over the substrate 301 but not directly over the bridge die 304-1. In the example shown in FIG. 3A, the die 304-2 may also be coupled with the substrate 301 via conductive interconnects 302-3, e.g., in the region where the footprint of the die 304-2 extends beyond the edge of the bridge die 304-1. Like the conductive interconnects 302-1, The conductive interconnect 302-3 may include a solder material 228 between conductive contacts 326-6 and conductive contacts 326-7. The conductive interconnects 302-3 may have a relatively wider width than the fine-pitch interconnects 302-12, 302-13 between the bridge die 304-1 and the die 304-2. In some examples, the conductive interconnects 302-3 may have a width that is substantially the same as the wider interconnects 302-11, 302-14 that are interleaved with the fine-pitch interconnects 302-12, 302-13 between the bridge die 304-1 and the die 304-2. In other examples, the interconnects 302-3 may have a width that is smaller than or greater than the width of the interconnects 302-11, 302-14.

In the example illustrated in FIG. 3A, the bridge die 304-1 may be embedded in the substrate 301, e.g., at least partially within a dielectric material 330 of one or more of the interconnect layers 321 of the substrate 301. In the example illustrated in FIG. 3A, the embedded bridge die 304-1 is coupled with the substrate via a plurality of conductive interconnects 302-2. The plurality of interconnects 302-2 include a solder material 228 (e.g., solder bumps or solder joints) between conductive contacts 326-4 and conductive contacts 326-5. The conductive contacts 326-5 are on a side or face 352 of the bridge die 304-1 that is facing the substrate (e.g., on a bottom face or substrate-facing side). The conductive contacts 326-4 are on and coupled with an interconnect layer 321 over which the 304-1 is disposed. In the example illustrated in FIG. 3A, the conductive interconnects 302-2 between the bridge die 304-1 and the substrate 301 have a width 334 that is about the same or larger than the width 332 of the interleaved wide interconnects between the bridge die 304-1 and 304-2.

In some examples, including the wider interconnects interleaved with smaller interconnects in a fine-pitch interconnect region may enable a vertical power path (shown with the dashed line arrow 360) from the substrate 301 to the fine-pitch interconnect region between the bridge die 304-1 and the die 304-2. For example, the wider conductive interconnects interleaved in the fine-pitch region (e.g., the interconnect 302-11) can be aligned with wide interconnects between the bridge die 304-1 and the substrate (e.g., the interconnect 302-21) to enable supplying a higher current density to the die 304-2 in a region with fine-pitch interconnects. In some examples, a wider interconnect (such as the interconnect 302-11) may carry significantly more current (e.g., 6-7 times) than smaller-width interconnects (such as the interconnect 302-12). Thus, by forming a vertical power path through the bridge die 304-1, fewer interconnects in the bridge die 304-1 may be needed to supply power to the die 304-2. Using fewer interconnects in the bridge die 304-1 to supply power to the die 304-2 may make more metal layer resources in the bridge die 304-1 available for I/O signals, which may enable increasing the signal rate possible for a given die stack and/or enable reducing the metal layer count in the bridge die 304-1. Additionally, the vertical power delivery path shown in FIG. 3A may enable providing power throughout the fine-pitch bump field between the bridge die 304-1 and the die 304-2.

FIG. 3B illustrates a cross-sectional side view of another example of a microelectronic assembly 300B that has a high-density interconnect region with mixed bump widths. The microelectronic assembly 300B of FIG. 3B is substantially the same as the microelectronic assembly 300A depicted in FIG. 3A; however, the microelectronic assembly 300B of FIG. 3B is shown to have multiple conductive pillars or vias 370 coupled with a single conductive contact 326-5 and extending through at least one layer of the bridge die 304-1. For example, FIG. 3B illustrates four conductive vias 370 coupled with a single one of the conductive contacts 326-5 and extending through one or more layers of the bridge die 304-1; however, other examples may include fewer than or more than four vias coupled with the conductive contact 326-5 (e.g., one, two, three, or more than four conductive vias). In the example illustrated in FIG. 3B, lines are used to represent multiple interconnect layers 372 of the bridge die 304-1 over a substrate 376 (e.g., over a silicon substrate) of the bridge die 304-1, and the conductive vias 370 may extend through (e.g., entirely through) the substrate 376 of the bridge die 304-1. In one such example, one or more of the conductive vias 370 may be coupled with one or more of the interconnect layers 372 over the substrate 376. In other examples, one or more of the conductive vias may extend entirely through the bridge die 304-1 (e.g., from the face 352 to the face 350). In one such example, a conductive via 370 may be coupled (e.g., in contact with, e.g., in direct contact with), one of the conductive contacts 326-5 on the face 352 and one of the conductive contacts 326-1 on the face 350.

Although some examples described herein refer to embedded bridge dies, in other examples, a microelectronic assembly that has a high-density interconnect region with mixed bump widths may include a bridge die that is not embedded. For example, referring to FIG. 3B, layer 374 may be considered the substrate, and the bridge die 304-1 may be over and bonded with the substrate (over and bonded with the layers 374) rather than being embedded in a cavity in a substrate.

Thus, FIGS. 3A and 3B illustrate examples of microelectronic assemblies that have a high-density interconnect region with mixed bump widths that may support a vertical power delivery path to the die 304-2 through the bridge die 304-1. The bridge die 304-1 is over one or more layers of the substrate (and may be embedded or not embedded in the substrate), and the die 304-2 may have a footprint that extends beyond the bridge die 304-1. Power may be delivered to the die 304-2 through a conductive interconnect 302-21 between the bridge die 304-1 and the substrate 301 and through one or more conductive vias coupled with the interconnect 302-21 and that extend from the interconnect 302-21 through at least one layer of the bridge die.

FIG. 4 is cross-sectional side view of an example microelectronic assembly 400 according to some embodiments of the present disclosure. The microelectronic assembly 400 is an example assembly that includes a glass core 403. A glass core 403 may further include through-glass vias (TGVs) 410. TGVs 410 are shown in FIG. 4 as having straight sides; however, in various embodiments, the TGVs 410 may have sides that taper toward a middle (e.g., have an hourglass shape), and/or have other irregularities depending on the processing conditions for generating TGVs 410. TGVs 410 may be formed of any suitable conductive material, such as copper, silver, nickel, gold, aluminum, or other metals or alloys. In some embodiments, a pitch of the TGVs 410 may be between 25 microns and 200 microns (e.g., between 75 microns and 150 microns).

A material of the glass core 403 may include glass, such as bulk transparent glass, and also may be referred to herein as “a glass layer.” As used herein, the term “core” refers to a structure (e.g., a portion of a glass layer) of any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, the glass core 403 may be bulk glass or a solid volume/layer of glass, as opposed to, e.g., materials that may include particles of glass, such as glass fiber reinforced polymers. Such glass materials are typically non-crystalline, often transparent, amorphous solids. In some embodiments, the glass core 403 may be an amorphous solid glass layer. In some embodiments, the glass core 403 may include silicon and oxygen, as well as any one or more of aluminum, boron, magnesium, calcium, barium, tin, sodium, potassium, strontium, phosphorus, zirconium, lithium, titanium, and zinc. In some embodiments, the glass core 403 may include a material, e.g., any of the materials described above, with a weight percentage of silicon being at least about 0.5%, e.g., between about 0.5% and 50%, between about 1% and 48%, or at least about 23%. For example, if the glass core 403 is fused silica, the weight percentage of silicon may be about 47%. In some embodiments, the glass core 403 may include at least 23% silicon and/or at least 26% oxygen by weight, and, in some further embodiments, the glass core 403 may further include at least 5% aluminum by weight. In some embodiments, the glass core 403 may include any of the materials described above and may further include one or more additives such as Al₂O₃, B₂O₃, MgO, CaO, SrO, BaO, SnO₂, Na₂O, K₂O, SrO, P₂O₃, ZrO₂, Li₂O, Ti, and Zn. In some embodiments, the glass core 403 may be a layer of glass that does not include an organic adhesive or an organic material. The glass core 403 may be distinguished from, for example, the “prepreg” or “RF4” core of a printed circuit board (PCB) substrate which typically includes glass fibers embedded in a resinous organic material such as an epoxy. In some embodiments, a cross-section of the glass core 403 in an xz plane, an yz plane, and/or an xy plane of an example coordinate system, shown in FIG. 4, may be substantially rectangular.

The microelectronic assembly 400 may further include a first substrate 448-1 at the first surface 470-1 of the glass core 403 and a second substrate 448-2 at the second surface 470-2 of the glass core 403. The first and second substrates 448-1, 448-2 may include conductive pathways 496 (e.g., including conductive traces and/or conductive vias, as shown) through a dielectric material. The substrates 448-1, 448-2 may include a set of first conductive contacts 472 at the bottom surface of the substrate 448-1, 448-2 and a set of second conductive contacts 474 at the top surface of the substrate 448-1, 448-2, where the conductive pathways 496 electrically couple individual ones of the first and second conductive contacts 472, 474. In some embodiments, conductive contacts 474, 472 at respective first and second surfaces 470-1, 470-2 of the core 403 may be omitted.

The first and second substrates 448-1, 448-2 may be manufactured using any suitable technique, such as a semi-additive process, a subtractive etching technique, or other conventional substrate package techniques. In some embodiments, a dielectric material of the substrates 448-1, 448-2 may include bismaleimide triazine (BT) resin, polyimide materials, epoxy materials (e.g., glass reinforced epoxy matrix materials, epoxy buildup films, or the like), mold materials, oxide-based materials (e.g., silicon dioxide or spin on oxide), or low-k and ultra low-k dielectric (e.g., carbon-doped dielectrics, fluorine-doped dielectrics, porous dielectrics, and organic polymeric dielectrics). The TGVs 410 in the glass core 403 may electrically couple the first and second substrates 448-1, 448-2. As used herein, the glass core 403 with the second substrate 448-2 and/or the first substrate 448-1 may be referred to as a package substrate. TGVs 410 in glass core 403 may enable power, ground and signal connectivity to components located on either side of the glass core 403, for example, between dies 414-1, 414-2 and a circuit board 431.

The microelectronic assembly 400 may further include die 414-1 and die 414-2 electrically coupled to a top surface of the second substrate 448-2 by interconnects 450. In particular, conductive contacts 422 on a bottom surface of die 414-1, 414-2 may be electrically and mechanically coupled to conductive contacts 474 at a top surface of the second substrate 448-2 by interconnects 450. The dies 414-1 and 414-2 may be examples of the die 104-2, discussed above.

Interconnects 450 disclosed herein may take any suitable form, and may be an example of the interconnects 102 discussed above. In some embodiments, a set of interconnects 450 may include solder (e.g., solder bumps or balls that are subject to a thermal reflow to form the interconnects 450). Interconnects 450 that include solder may include any appropriate solder material, such as those discussed above. In some embodiments, interconnects 450 may include interconnects having different widths. For example, the interconnect 450-3 is between the interconnects 450-1 and 450-2, where the interconnects 450-1 and 450-2 have a smaller width than the interconnect 450-3. Although FIG. 4 shows dies 414-1, 414-2 electrically coupled to substrate 448-2 by interconnects 450, dies 414-1, 414-2 may be electrically coupled by any suitable interconnects.

The microelectronic assembly 400 of FIG. 4 may also include a bridge die 402. A bridge die 402 may be at least partially within (e.g., embedded in) a dielectric material of the second substrate 448-2 (e.g., at least partially nested in a cavity). The bridge die 402 may be electrically coupled to dies 414-1 and die 414-2 by interconnects 450. In particular, conductive contacts 422 on the bottom surface of dies 414-1, 414-2 may be electrically and mechanically coupled to the conductive contacts 424 on the top surface of the bridge die 402 by interconnects 450. A bridge die 402 may be electrically coupled to conductive pathways 496 in the second substrate 448-2 by interconnects 420. In some embodiments, as shown, interconnects 420 may include solder. The bridge die 402 may be an example of the bridge die 304-1, discussed above. In some embodiments, a bridge die 402 may be omitted.

The microelectronic assembly 400 of FIG. 4 may also include an insulating material 435 that encapsulates the dies 414-1 and 414-2 (e.g., on and around the dies 414-1 and 414-2 and interconnects 450). The insulating material 435 may extend from a top surface of the second substrate 448-2 to a top surface of the dies 414-1 and 414-2. In some embodiments, the insulating material 435 may be a mold material, such as an organic polymer with inorganic silicon oxide or aluminum oxide particles, a resin material, or an epoxy material. In some embodiments (not shown) other components, such as heat sinks may be coupled to microelectronic assembly 400 based on particular needs.

The microelectronic assembly 400 of FIG. 4 may also include an underfill material 427. In some embodiments, the underfill material 427 may extend between the dies 414-1, 414-2 and the second substrate 448-2 around the associated interconnects 450. In some embodiments, the underfill material 427 may be between the bottom surface of the bridge die 402 and the second substrate 448-2 (not shown). The underfill material 427 may be an insulating material, such as an appropriate epoxy material or any other suitable insulator material, such as those discussed above.

The microelectronic assembly 400 of FIG. 4 may also include a circuit board 431. In particular, conductive contacts 472 on a bottom surface of the first substrate 448-1 may be electrically coupled to conductive contacts 446 on a top surface of circuit board 431 by interconnects 490. Interconnects 490 disclosed herein may take any suitable form, including solder balls for a ball grid array arrangement, pins in a pin grid array arrangement or lands in a land grid array arrangement, or any of the forms described above with reference to interconnects 450. As shown in FIG. 4, in some embodiments, a set of interconnects 490 may include solder 436 (e.g., solder bumps or balls that are subject to a thermal reflow to form the interconnects 490). In some embodiments, the interconnects 490 disclosed herein may have a pitch between about 50 microns and 300 A microns. In some embodiments, an underfill material 427 may extend between the first substrate 448-1 and the circuit board 431 around the associated interconnects 490. The circuit board 431 may be a motherboard, for example, and may have other components attached to it. The circuit board may include conductive pathways and other conductive contacts for routing power, ground, and signals through the circuit board, as known in the art. In some embodiments, the interconnects 490 may not couple to a circuit board 431, but may instead couple to another IC package, an interposer, or any other suitable component.

In some embodiments, one or more levels of solder resist (e.g., epoxy liquid, liquid photoimageable dielectrics, dry film photoimageable dielectrics, acrylics, solvents) may be provided in an IC package described herein and may not be labeled or shown to avoid cluttering the drawings. Solder resist may be a liquid or dry film material including photoimageable dielectric materials. In some embodiments, solder resist may be non-photoimageable.

Although FIG. 4 illustrates only the interface between the bridge die 402 and the die 414-2 as including mixed-width interconnects, other interfaces of the microelectronic assembly 400 may also, or alternatively, include mixed-width interconnects in accordance with examples described herein. For example, the interconnects 450 between the bridge die 402 and the die 414-1 may also, or alternatively, include wider interconnects interleaved with fine-pitch interconnects. In another example, the interconnects 420 between the bridge die 402 and the substrate 448-2 and/or the interconnects 490 between the substrate 448-1 and the circuit board 431 may include wider interconnects interleaved with fine-pitch interconnects.

FIGS. 5A-5E illustrate examples of interconnect patterns in which smaller-width interconnects and larger-width interconnects are interleaved. The interconnect patterns of FIGS. 5A-5E are examples of patterns along a plane substantially parallel with the die or substrate, where the plane intersects the interconnects with mixed widths. For example, referring to FIG. 1A, the patterns of FIGS. 5A-5E may be along a plane AA shown in FIG. 1A (e.g., in an xy plane intersecting the interconnects). Different interconnects may be arranged/configured in an assembly to transmit signals, provide power, enable testing, and/or provide ground. For example, a power interconnect may be coupled with a voltage source, a ground interconnect may be coupled with ground, and an I/O interconnect may be coupled with another I/O interconnect/data signal line (e.g., to enable the transmission of data between dies). An interconnect may be considered coupled with a data signal line if it is actually coupled with a data signal line, or if it is configured to be coupled with a data signal line when the interconnect is included in an assembly and/or system. An interconnect may be considered coupled with a voltage source or ground if it is actually coupled with a voltage source or ground, or if it is configured to be coupled with a voltage source or ground when the interconnect is included in an assembly and/or system. Being coupled with a voltage source, ground, or data signal line does not indicate that an assembly or system is actively connected to a power source and/or actively powered; in other words, an interconnect may be considered coupled with a voltage source, ground, or data signal even if the assembly that includes the interconnect is powered off and disconnected from a power source.

FIGS. 5A-5E use patterns to show an insulator material 523 and different types of interconnects (e.g., whether the interconnect is an I/O interconnect, power interconnect, or ground interconnect). For example, different patterns are used to show I/O interconnects 550, power interconnects 551 and 552 (where the power interconnects 551 may represent lower power/lower voltage interconnects than the power interconnects 552), and ground interconnects 553. Some interconnects may be arranged/configured to provide more than one function. For example, some interconnects may be I/O interconnects that may also be used for testing. Similarly, some interconnects may be power or ground interconnects that may also be used for testing.

Turning first to FIG. 5A, the interconnect pattern 500A includes rows 524 of fine-pitch interconnects with a first width, including a row of power interconnects 551 between rows of I/O interconnects 550. The pattern 500A also includes a row 522 of ground interconnects 553 with the first width and a row 520 of power interconnects 552 with the first width adjacent to the row 522. The pattern 500A of FIG. 5A also includes rows 526 and 528 that are identical to the rows 520 and 522, respectively.

In the example illustrated in FIG. 5A, power interconnects 552 and ground interconnects 553 that have a second width that is greater than the first width are interleaved with the smaller-width interconnects in the rows 520 and 522. For example, the interconnect 553-1 with the second width is between the interconnects 552-2 and 552-3 in a first line that intersects the interconnects 552-2 and 552-3 (e.g., a line parallel to the y-axis shown in FIG. 5A). Similarly, the interconnect 553-1 is between the interconnects 553-2 and 553-3 in a second line that intersects the interconnects 553-2 and 553-3 (e.g., a line parallel to the y-axis shown in FIG. 5A). Thus, the pattern 500A includes a first row 520 of interconnects with the first width and a second row 522 of interconnects with the first width adjacent to, substantially parallel with, and substantially aligned with the first row of interconnects. The interconnect 553-1 is between first interconnects of the first row 520 and between second interconnects of the second row 522 (e.g., between the interconnects 552-5 and 552-3 in the row 520 and between the interconnects 553-2 and 553-3 in the row 522). In the example illustrated in FIG. 5A, because the interconnect 553-1 has a greater width than the interconnects on either side of the interconnect 553-1 (e.g., about twice the width in the example shown in FIG. 5A), the interconnect 553-1 may be inline with both rows 520 and 522 of smaller-width interconnects.

In the example illustrated in FIG. 5A, the larger-width interconnects are surrounded on two or three sides by smaller-width interconnects (where two opposing “sides” of an interconnect may refer to two parallel tangent lines on the perimeter of the interconnect in a cross-section in a plane parallel with the die or substrate, e.g., in the xy plane). For example, the interconnect 552-5 is adjacent to a first side of the interconnect 553-1 and the interconnect 552-7 is adjacent to the interconnect 553-1 on a second side of the interconnect 553-1 that is opposite the first side. Another interconnect 550-1 is adjacent to a third side of the interconnect 553-2. Viewed another way, the interconnect 553-1 is between and adjacent to the interconnect 552-5 and the interconnect 552-7 in a first line in a plane substantially parallel with a die or substrate (e.g., along the y-axis), and the interconnect 550-1 is adjacent to the interconnect 553-1 in a second line in the plane that is substantially orthogonal to the first line (e.g., along the x-axis).

Also as illustrated in FIG. 5A, a plurality of smaller-width interconnects are between two larger-width interconnects. For example, the interconnects 552-2, 552-6, and 552-5 are between the interconnect 552-1 and the interconnect 553-1. Similarly, the interconnects 552-7 and 552-3 are between the interconnect 553-1 and 552-4.

FIG. 5B illustrates another interconnect pattern 500B in which smaller-width interconnects and larger-width interconnects are interleaved. The interconnect pattern 500B of FIG. 5B is similar to the pattern 500A of FIG. 5A, but differs in that the pattern 500B includes a dedicated larger bump region 560 in addition to the region 562 that is primarily a fine-pitch interconnect region, but which includes larger width bumps interleaved with smaller-pitch bumps. The larger bump region 560 illustrated in FIG. 5B includes power interconnects 551, power interconnects 552, and ground interconnects 553. In some examples, the larger-width interconnects in the region 562 and the interconnects in the region 560 may be used to deliver power and/or perform sort testing.

FIG. 5C illustrates another interconnect pattern 500C in which smaller-width interconnects and larger-width interconnects are interleaved. The pattern 500C is similar to the pattern 500A in that larger-width interconnects are between smaller-width interconnects, and where a larger width interconnect is inline with two rows of smaller-width interconnects (e.g., the interconnect 552-8 between the interconnects 552 in the line or row 570 and between the interconnects 553 in the line or row 572). In the example illustrated in FIG. 5C, some of the larger-width interconnects are surrounded on four sides by smaller-width interconnects. For example, the interconnect 553-7 is between and adjacent to the interconnect 552-9 and the interconnect 552-8 in a first line in a plane substantially parallel with a die or substrate, and the interconnect 553-7 is between and adjacent to the interconnect 550-2 and the interconnect 550-3 in a second line in the plane, where the second line is substantially orthogonal to the first line.

FIG. 5D illustrates another interconnect pattern 500D in which smaller-width interconnects and larger-width interconnects are interleaved. The pattern 500D is similar to the pattern 500C illustrated in FIG. 5C, but differs due to the inclusion of larger-width interconnects 551-1 and 551-2, which may represent interconnects that couple with a different voltage source (e.g., a lower voltage source) than the interconnects 552.

FIG. 5E illustrates another interconnect pattern 500E in which smaller-width interconnects and larger-width interconnects are interleaved. The pattern 500E includes alternating lines or rows of larger-width interconnects and smaller-width interconnects. For example, the pattern 500E includes rows 584-1, 584-2, and 584-3 of interconnects with a first width, and rows 580-1, 580-2, 580-3, and 580-4 of interconnects with a second width that is greater than the first width. In the example illustrated in FIG. 5E, the row 580-2 of interconnects with the second width is between, adjacent to, and substantially parallel with one of the rows 584-1 and one of the rows 584-2. Thus, in the example illustrated in FIG. 5E, the smaller-width interconnects and larger-width interconnects are interleaved along one axis (e.g., the x-axis), whereas the patterns 500A, 500B, 500C, and 500D including interleaving along two axes (e.g., the x-axis and the y-axis).

Thus, FIGS. 5A-5E illustrate examples of interconnect patterns. The arrangement of interconnects and the types of interconnects shown in the example patterns of FIGS. 5A-5E may be combined and/or interchanged.

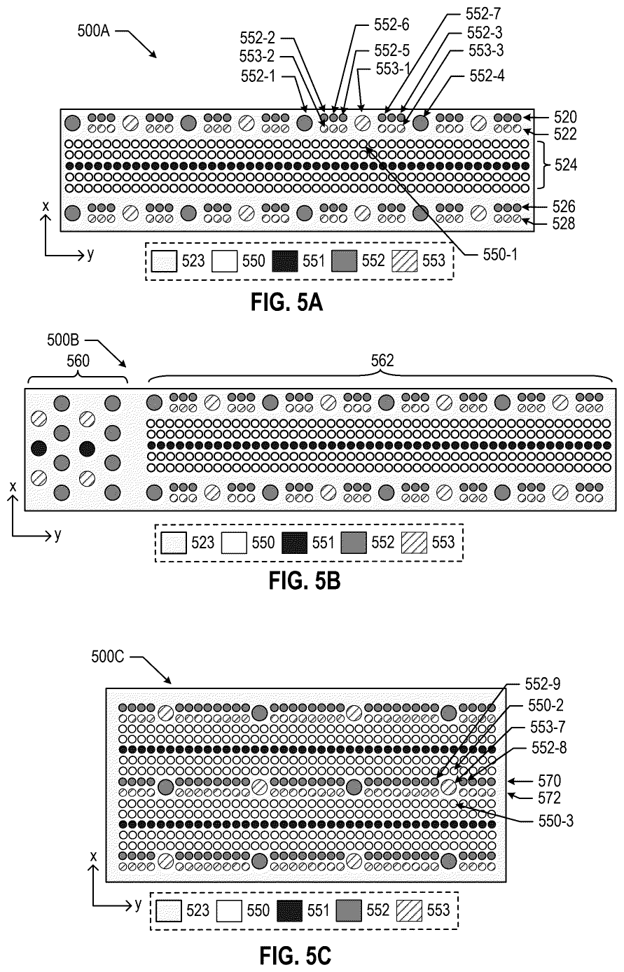

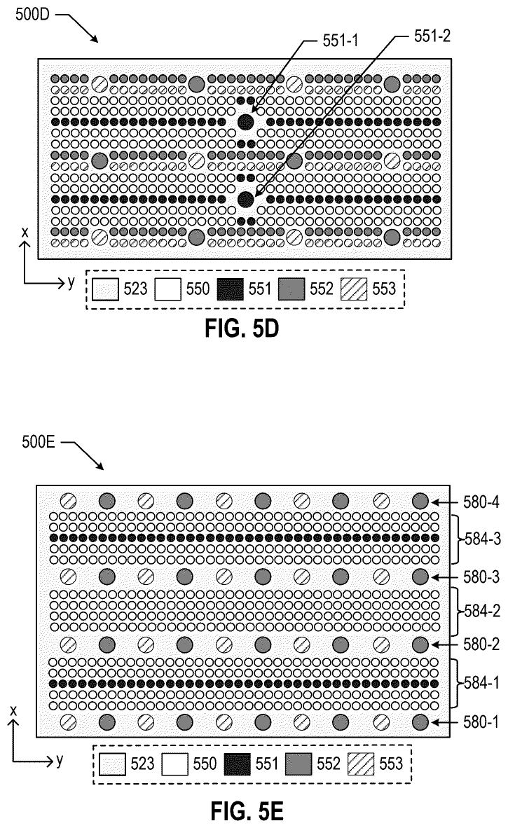

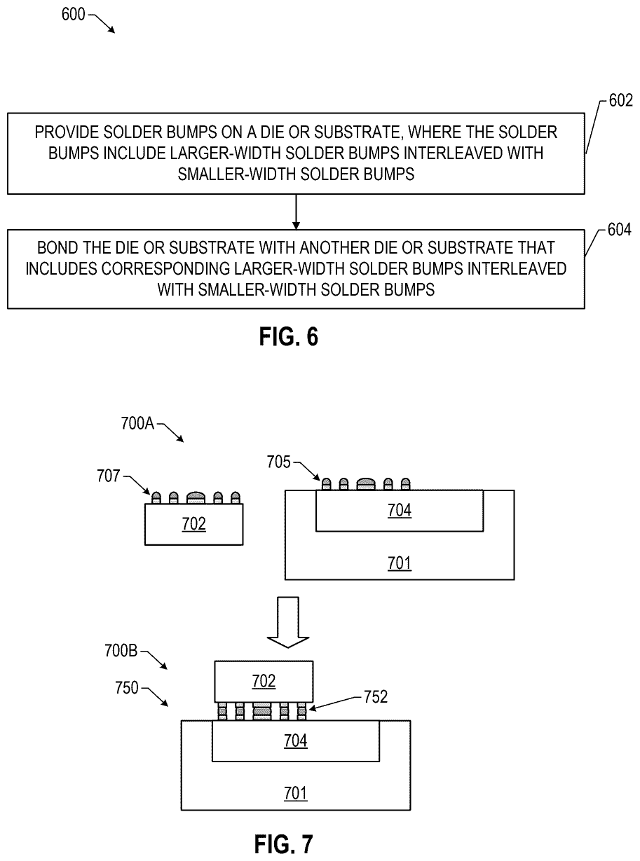

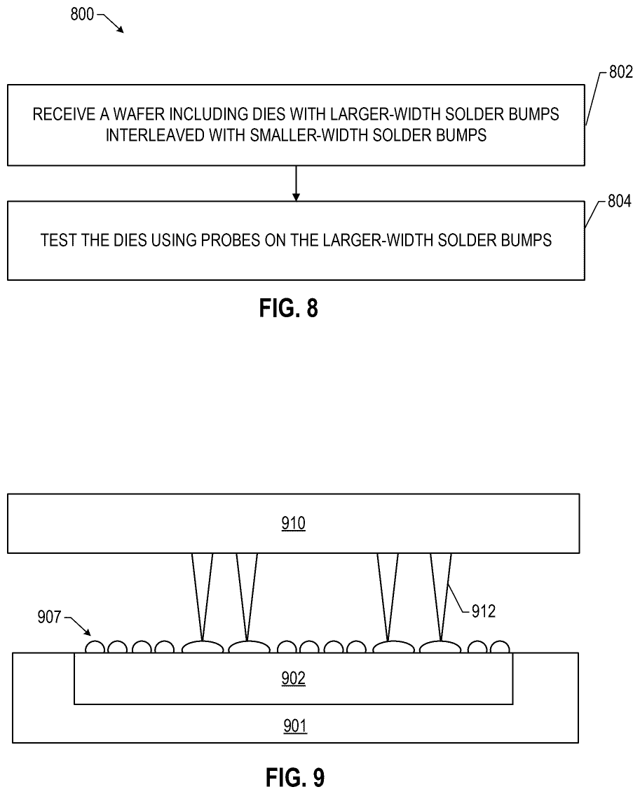

FIG. 6 is a flow diagram of a method 600 of making a microelectronic assembly with a high-density interconnect including mixed bump widths, in accordance with any example described herein. FIG. 8 is a flow diagram of a method 800 of performing sort testing on solder bumps of a wafer that includes a high-density interconnect including mixed bump widths. FIG. 7 illustrates cross-sectional side views of an example assembly at different stages of making a microelectronic assembly in accordance with the method of FIG. 6. FIG. 9 illustrates a cross-sectional view of the method of FIG. 8.

Although the operations of the methods of FIGS. 6 and 8 are illustrated once each and in a particular order, the operations may be repeated as desired. In addition, the example methods of FIGS. 6 and 8 may include other operations not specifically shown in FIGS. 6 and 8. For example, the method 600 of FIG. 6 may include embedding a bridge die in a substrate and/or forming/providing additional interconnect layers over a die or substrate, and/or various cleaning or planarization operations as known in the art. For example, in some embodiments, a substrate, as well as layers of various other materials subsequently deposited thereon, may be cleaned prior to, after, or during any of the processes of the methods described herein.

Turning to FIG. 6, the method 600 begins with a process 602 of providing solder bumps on a die or substrate, where the solder bumps include larger-width solder bumps interleaved with smaller-width solder bumps. The view 700A of FIG. 7 shows an example of a substrate 701 including an embedded bridge die 704, and solder bumps 705 on a side or face of the substrate 701. The substrate 701, bridge die 704, and the die 702 may be examples of any substrate and die described herein. The solder bumps may be provided in accordance with any suitable technique known in the art. In the example illustrated in FIG. 7, the solder bumps 705 may correspond with solder bumps 707 (e.g., correspond in terms of side and placement) on a die to be bonded with the substrate 701. The solder bumps 705 include larger-width bumps interleaved with smaller-width bumps, and may be in accordance with any pattern described herein (e.g., any of the patterns of FIGS. 5A-5E).

The method 600 continues with a process 604 of bonding the die or substrate with another die or substrate that includes corresponding larger-width solder bumps interleaved with smaller-width solder bumps. The view 700B of FIG. 7 depicts an example of a microelectronic assembly 750 that includes the die 702 bonded with the substrate 701 (e.g., bonded with the bridge die 704 in the substrate 701). The die 702 may be bonded with the substrate 701 using any suitable technique, such as thermocompression bonding. The resulting microelectronic assembly 750 includes interconnects 752 including a solder material, where larger-width interconnects are interleaved with smaller-width interconnects.

Turning to FIG. 8, the method 800 begins with a process 802 of receiving a wafer including dies with larger-width solder bumps interleaved with smaller-width solder bumps. FIG. 9 illustrates an example of a wafer 901 that includes a die 902 (e.g., a device region or die region in a pre-diced wafer) that has solder bumps 907 that include larger-width solder bumps interleaved with smaller-width solder bumps. The solder bumps 907 may be arranged in accordance with any of the examples described herein. The method 800 continues with a process 804 of testing the dies using probes on the larger-width solder bumps. FIG. 9 illustrates an example of a testing tool 910 including probes 912 that may make contact with various ones of the solder bumps 907 in order to perform testing, e.g., testing to determine electrical characteristics and performance and testing to identify non-functional dies.

Thus, a microelectronic assembly with a high-density interconnect region with mixed bump widths may integrate large-width bumps in fine-pitch regions of an active die to enable sort-on-solder with localized sort testing for large high-density interconnect regions with minimal impact to conductive bump area. Additionally, a high-density interconnect region with mixed bump widths may be arranged to enable vertical passthrough power delivery through a bridge die in a fine-pitch bump region.

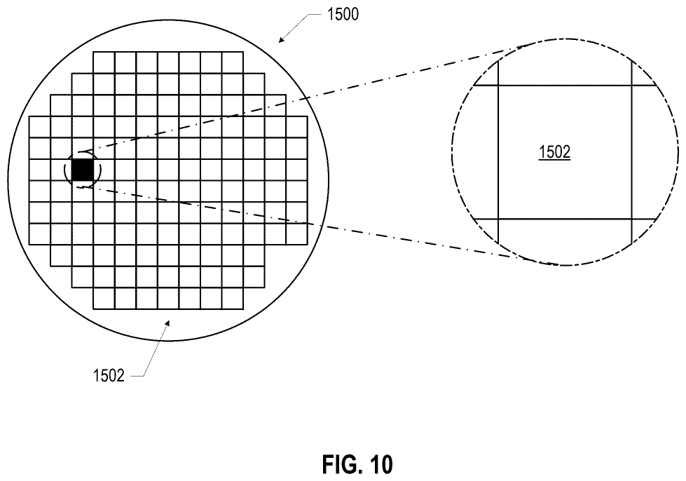

Microelectronic components and assemblies that have a high-density interconnect region with mixed bump widths in accordance with techniques described herein may be included in any suitable electronic component or electronic device. FIGS. 10-13 illustrate various examples of apparatuses that may include one or more of the IC structures or assemblies that have a high-density interconnect region with mixed bump widths as disclosed herein.

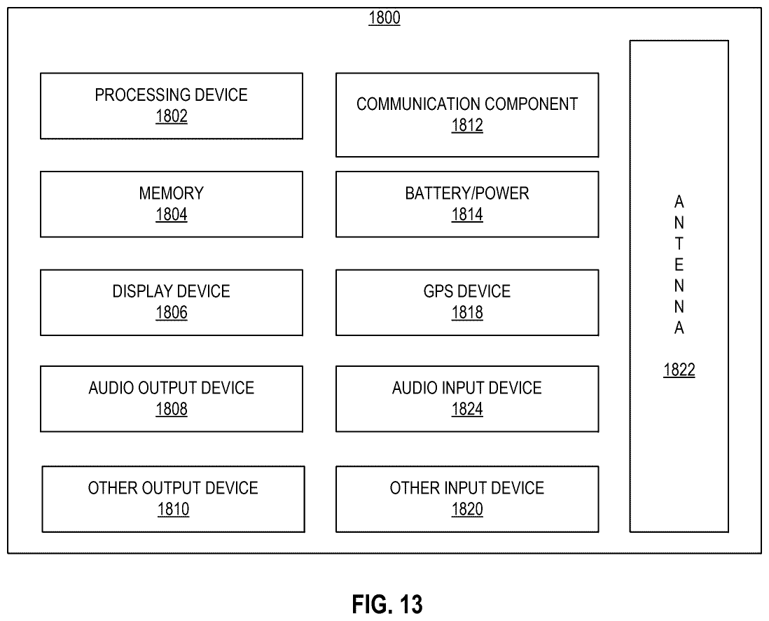

FIG. 10 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 13) or other logic that is configured to store information in the memory devices or execute instructions stored in the memory array.

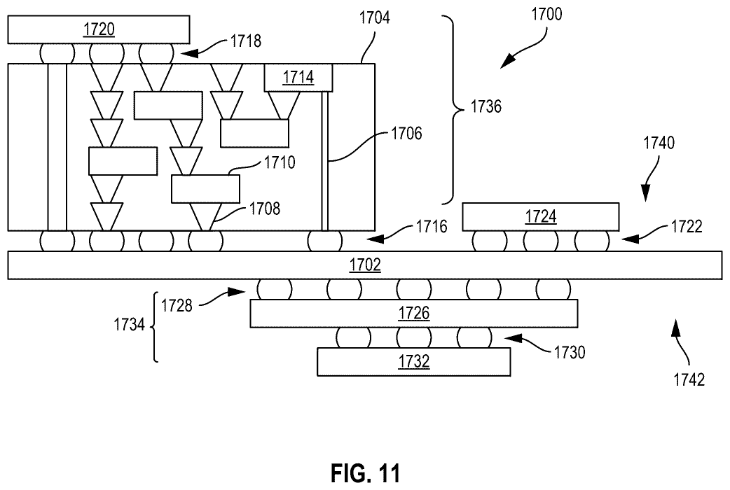

FIG. 11 is a side, cross-sectional view of an example IC package 1650 that may include a microelectronic component or assembly that has a high-density, fine bump pitch interconnect with mixed bump widths in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 11 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 11 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

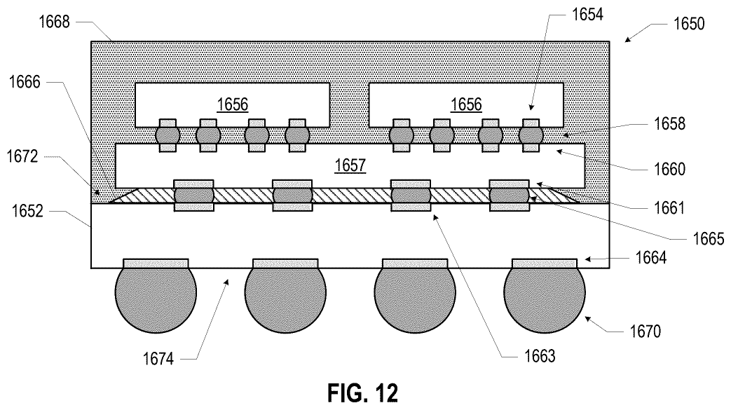

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 11 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 12.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 11 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fan-out (FO) package. Although two dies 1656 are illustrated in the IC package 1650 of FIG. 11, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 12 is a side, cross-sectional view of an IC device assembly 1700 that may include one or more IC packages or other electronic components (e.g., a die) or assemblies that have a high-density, fine bump pitch interconnect with mixed bump widths in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 11 (e.g., may include one or more IC structures in accordance with embodiments described herein).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 12 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 12), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 12, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 10), an IC device, or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 12, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 12 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 13 is a block diagram of an example electrical device 1800 that may include a microelectronic component or assembly that has a high-density, fine bump pitch interconnect with mixed bump widths in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 13 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 13, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides a microelectronic assembly, including a first die; a second die over and bonded with the first die; and a plurality of coplanar interconnects including a solder material, where the plurality of coplanar interconnects are between and coupled with the first die and the second die, and where the plurality of coplanar interconnects includes a first interconnect and a second interconnect with a first width (e.g., the first and second interconnects are small bumps), and a third interconnect (e.g., a large bump) between the first interconnect and the second interconnect, where the third interconnect has a second width that is greater than the first width.

Example 2 provides the microelectronic assembly of example 1, where: the second width is about 1.5 to 8 times greater than the first width.

Example 3 provides the microelectronic assembly of any one of examples 1-2, further including a first row of interconnects with the first width (e.g., small bumps); and a second row of interconnects with the first width (e.g., small bumps) adjacent to, substantially parallel with, and substantially aligned with the first row of interconnects, where: the third interconnect is between first interconnects of the first row and between second interconnects of the second row (e.g., and inline with the first row and second row).

Example 4 provides the microelectronic assembly of any one of examples 1-3, where: the third interconnect is between and adjacent to the first interconnect and the second interconnect in a first line in a plane substantially parallel with the first die, and a fourth interconnect with the first width (e.g., a small bump) is adjacent to the third interconnect in a second line in the plane that is substantially orthogonal to the first line (e.g., the larger conductive bump is surrounded on at least three “sides” by smaller conductive bumps).

Example 5 provides the microelectronic assembly of example 4, where: the third interconnect is between and adjacent to the fourth interconnect and a fifth interconnect with the first width (e.g., a small bump) in the second line (e.g., the larger conductive bump is surrounded on four “sides” by the smaller conductive bumps).

Example 6 provides the microelectronic assembly of any one of examples 1-3, further including a first row of interconnects having the first width, where the first row includes the first interconnect; a second row of interconnects having the first width, where the second row includes the second interconnect; and a third row of interconnects having the second width between, adjacent to, and substantially parallel with the first row and the second row, where the third row includes the third interconnect.

Example 7 provides the microelectronic assembly of any one of example 1-6, further including a substrate, where the first die is a bridge die embedded in the substrate.

Example 8 provides the microelectronic assembly of example 7, further including a fourth interconnect between the bridge die and the substrate, where the fourth interconnect has a third width that is greater than the first width; and a via through the bridge die between the third interconnect and the fourth interconnect.

Example 9 provides the microelectronic assembly of example 8, where: the third width is greater than or equal the second width (e.g., the bumps between the bridge die and the substrate may have a width that is greater than or equal to the large bumps interleaved with the small bumps between the bridge die and an IC die).

Example 10 provides the microelectronic assembly of examples 8 or 9, where the via is a first via, and where the microelectronic assembly further includes a second via through one or more of the layers of the bridge die between the third interconnect and the fourth interconnect, where the first via and the second via are coupled with a same bond pad of the fourth interconnect.

Example 11 provides the microelectronic assembly of any one of examples 1-9, further including a substrate, where the first die is a bridge die over one or more layers of the substrate, and where the second die has a footprint that extends beyond the first die; a fourth interconnect between the bridge die and the substrate; and a plurality of conductive vias coupled with the fourth interconnect and extending from the fourth interconnect through at least one layer of the bridge die.

Example 12 provides the microelectronic assembly of example 11, where: the bridge die includes a silicon substrate, and the plurality of conductive vias extend through (e.g., entirely through) the silicon substrate.

Example 13 provides the microelectronic assembly of example 12, where: the bridge die is embedded in the substrate.

Example 14 provides the microelectronic assembly of any one of examples 1-13, where: the first interconnect and the second interconnect are configured to be coupled with a voltage source or ground.

Example 15 provides the microelectronic assembly of any one of examples 1-13, where: the first interconnect and the second interconnect are configured to be coupled with a signal line.

Example 16 provides the microelectronic assembly of any one of examples 1-15, where: the third interconnect (e.g., larger bump) is coupled with two conductive contacts (e.g., pads) at a first face of the first die and one conductive contact at a second face of the second die, where the one conductive contact at the second face of the second die has a greater width than one of the two conductive contacts at the first face of the first die (e.g., two smaller pads on a bridge die or other die may be coupled with one larger bump).

Example 17 provides a microelectronic assembly, including a substrate; an IC die over and coupled with the substrate; a plurality of conductive interconnects including a solder material (e.g., solder joints) between and coupled with the substrate and the IC die, where the plurality of conductive interconnects include first conductive interconnects with a first width, and second conductive interconnects with a second with that is greater than the first width, where the second conductive interconnects are coplanar and interleaved with the first conductive interconnects.

Example 18 provides the microelectronic assembly of example 17, where: an individual one of the second conductive interconnects is between a first and a second of the first conductive interconnects in a line in a plane that is substantially parallel with the substrate (e.g., there are small bumps on at least two opposing “sides” of the larger bump).

Example 19 provides the microelectronic assembly of example 18, where the line is a first line, and where: the individual one of the second conductive interconnects is adjacent to a third of the first conductive interconnects in a second line in the plane at a non-zero angle relative to the first line (e.g., there may be small bumps on at least three “sides” of the larger bump).

Example 20 provides the microelectronic assembly of example 19, where: the second line is substantially orthogonal to the first line.

Example 21 provides the microelectronic assembly of example 20, where: the individual one of the second conductive interconnects is between the third and a fourth of the first conductive interconnects in the second line (e.g., there are small bumps on four “sides” of the larger bump).

Example 22 provides the microelectronic assembly of any one of examples 17-21, where: the first conductive interconnects are arranged in a first line and a second line that is adjacent to and parallel with the first line, and one of the second conductive interconnects is between first and second conductive interconnects of the first line and a third and a fourth conductive interconnect of the second line.

Example 23 provides the microelectronic assembly of any one of examples 17-22, where: two or more of the first conductive interconnects (e.g., small bumps) are between a first and a second of the second conductive interconnects in a line substantially parallel with the substrate (e.g., there may be multiple small bumps between two of the larger bump).

Example 24 provides an IC die, including a device region including one or more transistors; a plurality of interconnect layers over the device region; a first solder bump on a side of the IC die, where the first solder bump has a first width; a second solder bump on the side of the IC die, where the second solder bump has the first width; and a (larger) third solder bump on the side of the IC die, where: the (larger) third solder bump has a second width that is greater than the first width, and the (larger) third solder bump is between the first solder bump and the second solder bump.

Example 25 provides the IC die of example 24, further including a first plurality of solder bumps on the side of the IC die, where an individual one of the first plurality of solder bumps has the first width, and where the first plurality of solder bumps includes the first solder bump; and a second plurality of solder bumps on the side of the IC die, where an individual one of the second plurality of solder bumps has the first width, and where the second plurality of solder bumps includes the second solder bump, where: the third solder bump is between the first plurality of solder bumps and the second plurality of solder bumps.

Example 26 provides the IC die of example 25, further including a fourth (larger) solder bump with the second width on the side of the IC die, where one or more of the first plurality of solder bumps are between the third (larger) solder bump and the fourth (larger) solder bump (e.g., one or more smaller bumps may be between two larger bumps).

Example 27 provides the IC die of any one of examples 24-26, where: the first plurality of solder bumps are arranged in a line in a plane substantially parallel with the device region, the line intersects the (larger) third solder bump, and the second plurality of solder bumps are arranged in the line.

Example 28 provides the IC die of example 27, where the line is a first line, and where: a third plurality of solder bumps are arranged in a second line substantially parallel with the first line, where an individual one of the third plurality of solder bumps has the first width, a fourth plurality of solder bumps are arranged in the second line, where an individual one of the fourth plurality of solder bumps has the first width, the third solder bump is between the third plurality of solder bumps and the fourth plurality of solder bumps, and the second line intersects the (larger) third solder bump.

Example 29 provides the IC die of example 27, where the line is a first line, and where the IC die further includes a fourth (small) solder bump with the first width adjacent to the (larger) third solder bump, where the fourth (small) solder bump is in a second line in the plane, and where the second line is substantially orthogonal to the first line.

Example 30 provides the IC die of example 29, further including a fifth (micro) solder bump with the first width adjacent to the (large) third solder bump, where the fifth solder bump is in the second line, and where the (large) third solder bump is between the fourth solder bump and the fifth solder bump.

Example 31 provides the IC die of any one of examples 24-30, where: the second width is about 1.5 to 8 times greater than the first width.

Example 32 provides the microelectronic assembly according to any one of examples 1-23 or the IC die according to any one of examples 24-32, where the microelectronic assembly or IC die includes or is a part of a central processing unit.

Example 33 provides the microelectronic assembly or IC die according to any one of examples 1-32, where the microelectronic assembly or IC die includes or is a part of a memory device.

Example 34 provides the microelectronic assembly or IC die according to any one of examples 1-33, where the microelectronic assembly or IC die includes or is a part of a logic circuit.

Example 35 provides the microelectronic assembly or IC die according to any one of examples 1-34, where the microelectronic assembly or IC die includes or is a part of input/output circuitry.

Example 36 provides the microelectronic assembly or IC die according to any one of examples 1-35, where the microelectronic assembly or IC die includes or is a part of a field programmable gate array transceiver.

Example 37 provides the microelectronic assembly or IC die according to any one of examples 1-36, where the microelectronic assembly or IC die includes or is a part of a field programmable gate array logic.

Example 38 provides the microelectronic assembly or IC die according to any one of examples 1-37, where the microelectronic assembly or IC die includes or is a part of a power delivery circuitry.

Example 39 provides an IC package that includes a microelectronic assembly or IC die according to any one of examples 1-38.

Example 40 provides the IC package according to example 39, further including a further IC component coupled to the microelectronic assembly or IC die.

Example 41 provides the IC package according to example 40, where the further IC component includes a package substrate.

Example 42 provides the IC package according to example 40, where the further IC component includes an interposer.

Example 43 provides the IC package according to example 40, where the further IC component includes a further assembly or die.

Example 44 provides a computing device that includes a carrier substrate and an IC die or microelectronic assembly coupled to the carrier substrate, where the IC die or microelectronic assembly is in accordance with any one of examples 1-38, or the IC die or assembly is included in the IC package according to any one of examples 39-43.

Example 45 provides the computing device according to example 44, where the computing device is a wearable or handheld computing device.

Example 46 provides the computing device according to examples 44 or 45, where the computing device further includes one or more communication chips.

Example 47 provides the computing device according to any one of examples 44-46, where the computing device further includes an antenna.

Example 48 provides the computing device according to any one of examples 44-47, where the carrier substrate is a motherboard.

Example 49 provides a process of making an IC die, providing solder bumps on an IC die, or making a microelectronic assembly in accordance with any of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A microelectronic assembly, comprising:
a first die;
a second die over and bonded with the first die; and
a plurality of coplanar interconnects comprising a solder material, wherein the plurality of coplanar interconnects are between and coupled with the first die and the second die, and wherein the plurality of coplanar interconnects comprises:
a first interconnect with a first width,
a second interconnect with the first width, and
a third interconnect between the first interconnect and the second interconnect, wherein the third interconnect has a second width that is greater than the first width.

2. The microelectronic assembly of claim 1, wherein:
the second width is about 1.5 to 8 times greater than the first width.

3. The microelectronic assembly of claim 1, further comprising:
a first row of interconnects with the first width; and
a second row of interconnects with the first width adjacent to, substantially parallel with, and substantially aligned with the first row of interconnects, wherein:
the third interconnect is between first interconnects of the first row and between second interconnects of the second row.

4. The microelectronic assembly of claim 1, wherein:
the third interconnect is between and adjacent to the first interconnect and the second interconnect in a first line in a plane substantially parallel with the first die, and
a fourth interconnect with the first width is adjacent to the third interconnect in a second line in the plane that is substantially orthogonal to the first line.

5. The microelectronic assembly of claim 4, wherein:
the third interconnect is between and adjacent to the fourth interconnect and a fifth interconnect with the first width in the second line.

6. The microelectronic assembly of claim 1, further comprising:
a first row of interconnects having the first width, wherein the first row comprises the first interconnect;
a second row of interconnects having the first width, wherein the second row comprises the second interconnect; and
a third row of interconnects having the second width between, adjacent to, and substantially parallel with the first row and the second row, wherein the third row comprises the third interconnect.

7. The microelectronic assembly of claim 1, further comprising:
a substrate, wherein the first die is a bridge die embedded in the substrate.

8. The microelectronic assembly of claim 7, further comprising:
a fourth interconnect between the bridge die and the substrate, wherein the fourth interconnect has a third width that is greater than the first width; and
a via through one or more layers of the bridge die between the third interconnect and the fourth interconnect.

9. The microelectronic assembly of claim 8, wherein:
the third width is greater than or equal the second width.

10. The microelectronic assembly of claim 8, wherein the via is a first via, and wherein the microelectronic assembly further comprises:
a second via through one or more of the layers of the bridge die between the third interconnect and the fourth interconnect, wherein the first via and the second via are coupled with a same bond pad of the fourth interconnect.

11. The microelectronic assembly of claim 1, further comprising:
a substrate, wherein the first die is a bridge die over one or more layers of the substrate, and wherein the second die has a footprint that extends beyond the first die;
a fourth interconnect between the bridge die and the substrate; and
a plurality of conductive vias coupled with the fourth interconnect and extending from the fourth interconnect through at least one layer of the bridge die.

12. The microelectronic assembly of claim 11, wherein:
the bridge die comprises a silicon substrate, and
the plurality of conductive vias extend through the silicon substrate.

13. The microelectronic assembly of claim 12, wherein:
the bridge die is embedded in the substrate.

14. The microelectronic assembly of claim 1, wherein:
the first interconnect and the second interconnect are configured to be coupled with a voltage source or ground.

15. The microelectronic assembly of claim 1, wherein:
the first interconnect and the second interconnect are configured to be coupled with a signal line.

16. The microelectronic assembly of claim 1, wherein:
the third interconnect is coupled with two conductive contacts at a first face of the first die and one conductive contact at a second face of the second die, wherein the one conductive contact at the second face of the second die has a greater width than one of the two conductive contacts at the first face of the first die.

17. A microelectronic assembly, comprising:
a substrate;
an integrated circuit (IC) die over and coupled with the substrate; and
a plurality of conductive interconnects comprising a solder material between and coupled with the substrate and the IC die, wherein the plurality of conductive interconnects comprise:
first conductive interconnects, wherein a first conductive pad of one of the first conductive interconnects has a first width, and
second conductive interconnects, wherein a second conductive pad of one of the second conductive interconnects has a second with that is greater than the first width, and wherein the second conductive interconnects are coplanar and interleaved with the first conductive interconnects.

18. The microelectronic assembly of claim 17, wherein:
an individual one of the second conductive interconnects is between a first and a second of the first conductive interconnects in a line in a plane that is substantially parallel with the substrate.

19. An integrated circuit (IC) die, comprising:
a device region comprising one or more transistors;
a plurality of interconnect layers over the device region;
a first solder bump on a side of the IC die, wherein the first solder bump has a first width;
a second solder bump on the side of the IC die, wherein the second solder bump has the first width; and
a third solder bump on the side of the IC die, wherein:
the third solder bump has a second width that is greater than the first width, and
the third solder bump is between the first solder bump and the second solder bump.

20. The IC die of claim 19, further comprising:
a first plurality of solder bumps on the side of the IC die, wherein an individual one of the first plurality of solder bumps has the first width, and wherein the first plurality of solder bumps includes the first solder bump; and
a second plurality of solder bumps on the side of the IC die, wherein an individual one of the second plurality of solder bumps has the first width, and wherein the second plurality of solder bumps includes the second solder bump, wherein:
the third solder bump is between the first plurality of solder bumps and the second plurality of solder bumps.
